(19) United States
(12) Patent Application Publication
(10) Pub. No.: US 2009/0223435 A1
(43) Pub. Date: Sep. 10, 2009

(54) SUBSTRATE PANEL

(75) Inventors: Wen-Jeng FAN, Hukou Shiang (TW); Tsai-Chuan Yu, Hukou Shiang (TW); Ching-Wei Hung, Hukou Shiang (TW)

Correspondence Address: Muncy, Geissler, Olds & Lowe, PLLC, P.O. BOX 1364, FAIRFAX, VA, 22038-1364, US

(73) Assignee: POWERTECH TECHNOLOGY CORPORATION

(21) Appl. No.: 12/042,107

(22) Filed: Mar. 4, 2008

(51) Int. Cl. H05K 1/02

(52) U.S. Cl. 116/240

(57) ABSTRACT

A substrate panel is revealed, comprising a plurality of substrate strips where each substrate strip has a plurality of substrate units and a plurality of appropriative ID marks. Each ID mark is corresponding to and formed on each substrate unit. All of the ID marks are different in a manner to simultaneously recognize both the relative locations of the substrate units to the substrate strips and the relative locations of the substrate strips to the substrate panel. In a preferred embodiment, the ID marks are disposed on exposed surfaces of the substrate units so that it is still visible after semiconductor packaging. Therefore, during or after semiconductor packaging processes, any defect found can be traced back by the ID marks on the substrate units to recognize the locations of the substrate units in the substrate panel for failure analysis to improve PCB manufacturing processes or semiconductor packaging processes for better production yields.

### FIELD OF THE INVENTION

The present invention relates to a printed circuit board, especially to a substrate panel including a plurality of substrate strips for semiconductor packaging processes.

### BACKGROUND OF THE INVENTION

Substrate panels are manufactured by conventional printed circuit board processes with sequential processing and inspection steps. Then substrate panels are routed to form a plurality of substrate strips for semiconductor packaging. Each substrate strip includes a plurality of substrate units as chip carriers for semiconductor packages. Normally, the conventional processes for manufacturing printed circuit boards comprises inner layer pretreatment, black oxidation, lamination, drilling, panel plating, etching, etc. During the PCB manufacturing processes, there are always some yield losses, especially in panel plating. Since the edge effect of the panel plating, the thickness of plating layer will be different at different substrate units in the substrate panel leading to substrate defects or poor substrate quality.

In the conventional substrate panels, there is only one batch number of production and one inspection number for each panel where batch numbers of the substrate panels are the same when manufactured in the same batch. During or after semiconductor packaging processes, the original locations of each substrate unit on the substrate strips or on the substrate panel cannot be recognized. Moreover, each substrate panel is singulated into a plurality of substrate strips at the beginning of the semiconductor packaging processes and each substrate strip is further separated into a plurality of substrate units at the end of the semiconductor packaging processes. Once defects are found in the substrate units, it is not possible to trace back to the original substrate panel to improve the manufacturing processes of printed circuit boards by production management, quality control, reliability analysis, or failure analysis. Currently, there is only a shipping ID number stuck on the semiconductor packages which can not trace the original location of the substrate units back to its location in the substrate strip and the substrate panel.

### SUMMARY OF THE INVENTION

The main purpose of the present invention is to provide a substrate panel with ID marks formed on substrate units to recognize the corresponding locations of each substrate unit in a substrate strip and in a substrate panel so that the manufacturing processes of printed circuit boards and semiconductor packaging processes can be improved by failure analysis.

The second purpose of the present invention is to provide a substrate panel with ID marks formed on the exposed surfaces of substrate units where the ID marks are still visible even after packaging. It is possible to trace the origins of the defects from semiconductor packaging processes back to printed circuit board manufacturing processes to improve manufacturing yield.

According to the present invention, a substrate panel comprises a plurality of substrate strips where each substrate strip has a plurality of substrate units and a plurality of ID marks each corresponding to and formed on each substrate unit. All of the ID marks in the substrate panel are different in a manner to simultaneously recognize both the relative locations of the substrate units to the substrate strips and the relative locations of the substrate strips to the substrate panel.

### DESCRIPTION OF THE DRAWINGS

FIG. 1 shows an exposed surface of a substrate panel according to the preferred embodiment of the present invention.

FIG. 2 shows a partial cross-sectional view of the substrate panel according to the preferred embodiment of the present invention.

FIG. 3 shows a partial substrate panel with an enlarged view of the substrate units according to the preferred embodiment of the present invention.

FIG. 4 shows one of the ID marks on the substrate panel according to the preferred embodiment of the present invention.

FIG. 5 shows a cross-sectional view of a semiconductor package utilizing one of the substrate units according to the preferred embodiment of the present invention.

### DETAIL DESCRIPTION OF THE INVENTION

Please refer to the attached drawings, the present invention will be described by means of embodiment below.

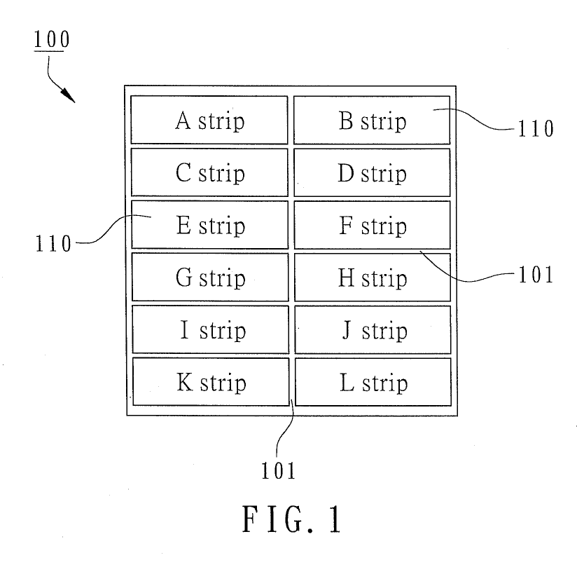

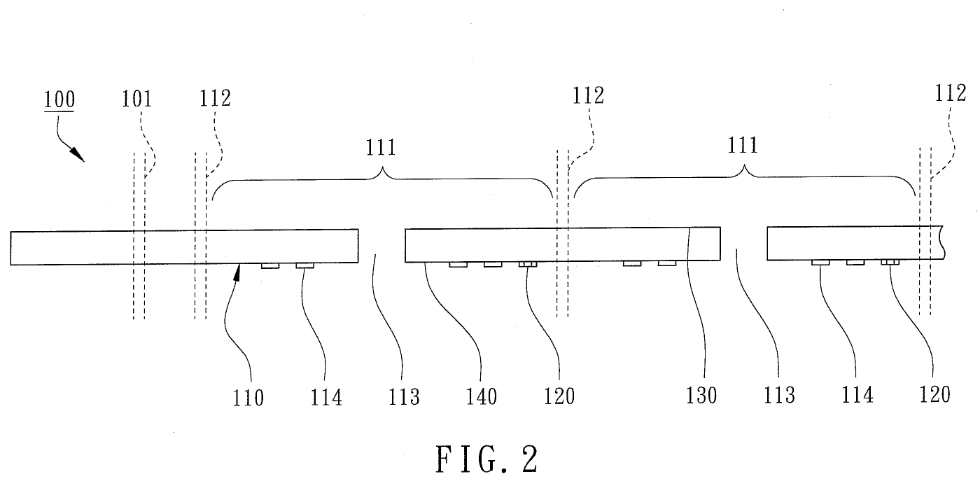

As shown in FIG. 1 and FIG. 2, a substrate panel 100 comprises a plurality of substrate strips 110 where each substrate strip 110 is defined by a plurality of first scribe line 101 around the peripheries of the substrate strips 110. The substrate panel 100 is a printed circuit board and is manufactured by PCB processes. In the present embodiment, the substrate panel 100 has twelve substrate strips 110 and are distinguished as A, B, C, . . . to L zones for all the twelve substrate strips 110. After manufacturing the substrate panel 110 and before semiconductor packaging processes, the substrate panel 100 is cut by a sawing or punching tool, not shown in the figure, along the first scribe lines 101 to singulate into a plurality of substrate strips 110.

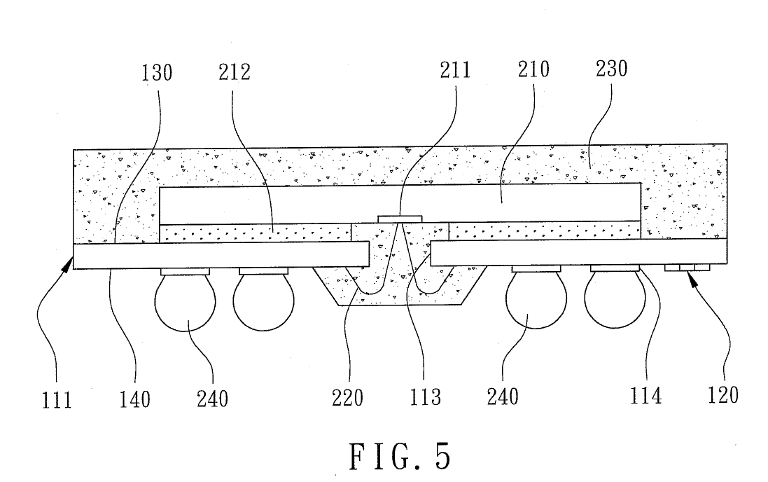

Each substrate strip 110 has a plurality of substrate units 111 arranged in an array and a plurality of ID (identification) marks 120 corresponding to the substrate units 111. A plurality of second scribe lines 112 are disposed around the peripheries of each substrate unit 111 and are enclosed by the first scribe lines 101 where the length of the second scribe line 112 is smaller than the one of the first scribe line 101 to define the substrate units 111. The substrate units 111 can be the chip carriers for memory cards, BGA, LGA or the other semiconductor packages. During semiconductor packaging, a plurality of substrate units 111 are integrally connected in a substrate strip 110 to transport and assemble as a workpiece during semiconductor packaging processes to facilitate mass production. Furthermore, each substrate strip 110 has a plurality of alignment holes, not shown in the figure, to facilitate automation. After semiconductor packaging processes, the substrate strip 110 is cut by a sawing tool, not shown in the figure, along the second scribe lines 112 to singulate into a plurality of semiconductor packages each including one of the substrate units 111 as shown in FIG. 5. Additionally, one of the ID marks 120 on the packaged substrate unit 111 is still visible from the semiconductor package.

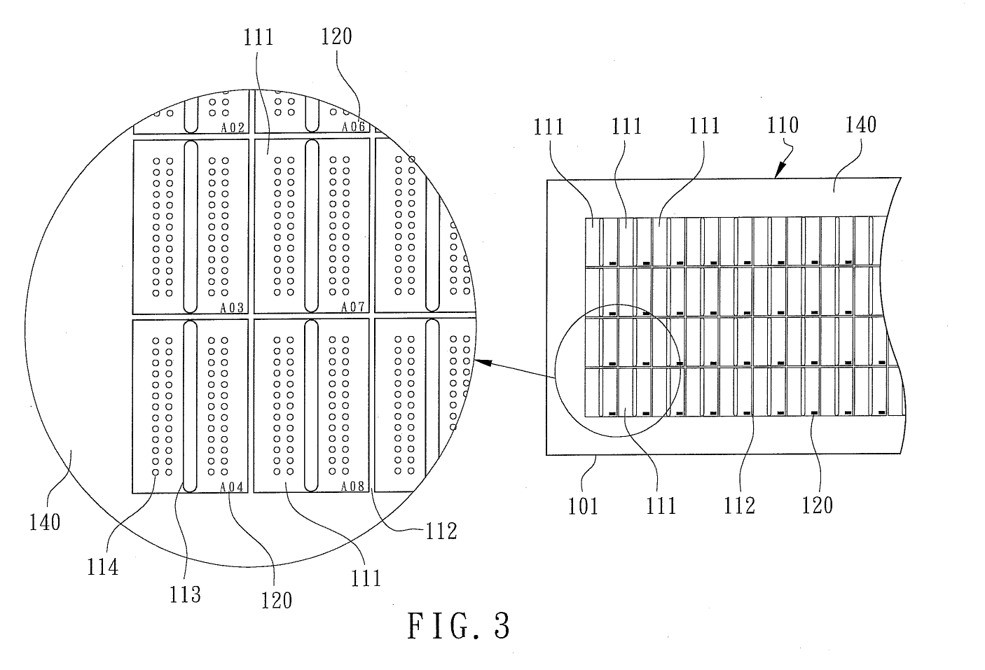

As shown in FIG. 2 and FIG. 3, each ID mark 120 is corresponding to and formed on each substrate unit 111. All of the ID marks 120 are different in a manner to simultaneously recognize both the relative locations of the substrate units 111 to the substrate strips 110 and the relative locations of the substrate strips 110 to the substrate panel 100. In this embodiment, each substrate unit 111 has a plurality of external pads 114 formed on an exposed surface 140. Preferably, the ID marks 120 are located within one of the corners of the substrate units 111 away from the external pads 114. More preferably, the ID marks 120 are integrally formed in the substrate units 111 so that the ID marks 120 are not lost or burned during the semiconductor packaging processes. The ID marks 120 are made of metal by etching a copper foil during PCB manufacturing processes of the substrate panel 100. In this embodiment, each substrate unit 111 further has a central slot 113 for wire-bonding processes of window BGA packages.

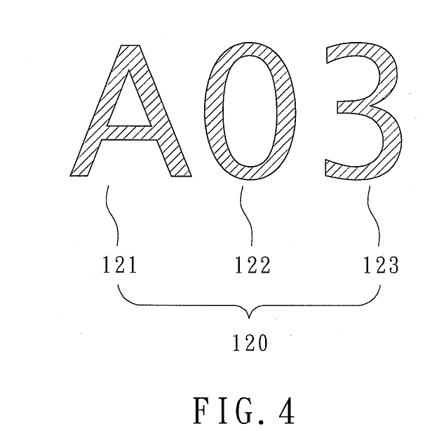

As shown in FIG. 3 and FIG. 4, each ID mark 120 includes a first symbol digit 121, a second symbol digit 122, and a third symbol digit 123 close in turn where the first symbol digit 121 can be the location code for the substrate strips 110 and the combination of the second symbol digit 122 and the third symbol digit 123 are the location codes for the substrate units 111 in the substrate strips 110 to manage all of the substrate units 111 in the substrate panel 100. The ID marks 120 are selected from numbers, letters, text, special symbols, graphs, or combination of all. In the present embodiment, the first symbol digit 121 can be selected twenty six letters from A to Z and the second symbol digit 122 and the third symbol digit 123 can be selected from Arabic numerals from 0 to 9. Accordingly, the first symbol digit 121 and the combination of the second symbol digit 122 and the third symbol digit 123 belong to two different coding systems for easy identifications. As shown in FIG. 4, in one embodiment, one of the ID marks 120 is formed on the substrate panel 100 where the first symbol digit 121 is “A” to represent the substrate unit 111 belonging to the substrate strip A which location in the substrate panel 100 is shown in FIG. 1. The second symbol digit 122 is “0” and the third symbol digit 123 is “3” to represent the corresponding location of the substrate unit 111 in the substrate strip 110. In the present embodiment, the second symbol digit 122 and the third symbol digit 123 are recognized as a serial number in decimal (base 10) or the other system. In different embodiment, the second symbol digit 122 can represent the Y-axis (vertical) location of the corresponding substrate unit 111 in a substrate strip 110 and the third symbol digit 123 can represent the X-axis (horizontal) location of the corresponding substrate unit 111 on a substrate strip 110 or vice versa. When a substrate strip 110 has more than nine rows or nine columns of substrate units, the second symbol digit 122 and the third symbol digit 123 are selected from letters in addition to Arabic numerals so that the second symbol digit 122 and the third symbol digit 123 are recognized as a serial number in hexadecimal (base 16) or hexatridecimal (base 36) system including ten numbers (0 to 9) and six letters (from A to F) or twenty six letters (from A to Z). For example, “A” represents tenth row or tenth column, and “D” represents thirteenth row or thirteenth column. Furthermore, another letters or code can be combined with the first symbol digit 121 such as AB or BC to represent a location of a substrate strip in a larger substrate panel.

To be more specific, as shown in FIG. 2, each of the substrate units 111 in the substrate panel 100 has an internal surface 130 opposing to the exposed surface 140 where the internal surface 130 means that the surface is configured for chip attaching or/and is mostly covered by an encapsulant during semiconductor packaging processes. The exposed surface 140 means the surface mostly exposed after semiconductor packaging processes such as a SMT surface including the external pads 114. Preferably, as shown in FIG. 3, the ID marks 120 are disposed on the exposed surface 140. After semiconductor packaging processes, the substrate units 111 are singulated by a sawing tool, not shown in the figure, along the second scribe lines 112 at the peripheries of the substrate units 111 to form a plurality of individual semiconductor packages, as shown in FIG. 5. The exposed ID marks 120 still can be recognized from the exposed surfaces 140 of the substrate units 111 after package singulation. Therefore, the semiconductor packages can be traced back to the corresponding locations of the substrate units on a substrate panel for failure analysis to improve manufacturing processes leading to better production yields.

In a preferred embodiment, after semiconductor packaging processes, these substrate units 110 carrying a chip become individual semiconductor packages. As shown in FIG. 5, a semiconductor package primarily comprises a substrate unit 111 with an ID mark 120, a chip 210, a plurality of bonding wires 220, and an encapsulant 230. The chip 210 is disposed on the internal surface 130 of the substrate units 111. In the present embodiment, the active surface of the chip 210 is attached to the internal surface 130 of the substrate unit 111 by a die-attaching material 212 such as a B-stage paste or a PI tape. A center slot 113 is disposed through the substrate unit 111 for passing a plurality of bonding wires 220 to electrically connect a plurality of bonding pads 211 of the chip 210 to the substrate unit 111. The encapsulant 230 is formed on the internal surface 130 of the substrate unit 111 and in the center slot 113 to encapsulate the chip 210 and the bonding wires 220 to provide protection and to avoid electrical short and contaminations. Furthermore, a plurality of external terminals 240 are disposed on the external pads 114 of the substrate unit 111. In the present embodiment, the external terminals 240 are disposed and bonded to the external pads 114 of the substrate unit 111 by solder ball placement or stencil printing with appropriate reflow to form BGA packages.

As shown in FIG. 4 and FIG. 5, each individual semiconductor package has an ID mark 120 unobviously exposed which can be recognized from the exposed surface 140 of the substrate unit 111 to know the corresponding locations on a substrate strip 110 of a substrate panel 100, but the ID mark 120 can be hidden when the semiconductor package is mounted on a PCB. When defects are found in the substrate units 111, it will be able to trace back to the relative location of the substrate unit 111 to a substrate strip 110 and the relative location of the utilized substrate strip 110 to the substrate panel 100 to point the root cause of the defects to improve manufacturing processes and to increase production yield.

The above description of embodiments of this invention is intended to be illustrative and not limiting. Other embodiments of this invention will be obvious to those skilled in the art in view of the above disclosure.

What is claimed is:

1. A substrate panel primarily comprising a plurality of substrate strips, wherein each substrate strip has a plurality of substrate units and a plurality of ID marl(s each corresponding to and formed on each substrate unit, all of the ID marks in the substrate panel are different in a manner to simultaneously recognize both the relative locations of the substrate units to the substrate strips and the relative locations of the substrate strips to the substrate panel.

2. The substrate panel as claimed in claim 1, wherein each substrate unit has an internal surface and an exposed surface, and wherein the ID marks are disposed on the exposed surfaces.

3. The substrate panel as claimed in claim 2, wherein each substrate unit further has a plurality of external pads on the exposed surfaces.

4. The substrate panel as claimed in claim 3, wherein each substrate unit further has a central slot.

5. The substrate panel as claimed in claim 2, wherein the ID marks are located within a plurality of corners of the corresponding substrate units.

6. The substrate panel as claimed in claim 1, wherein each ID mark includes a first symbol digit, a second symbol digit, and a third symbol digit close in turn wherein the first symbol digit is a location code for the substrate strips, the second symbol digit and the third symbol digit are the location codes for the substrate units.

7. The substrate panel as claimed in claim 6, wherein the first symbol digit is selected from letters, and wherein the second symbol digit and the third symbol digit are selected from Arabic numerals.

8. The substrate panel as claimed in claim 1, wherein the ID marks are integrally formed in the substrate units.

9. The substrate panel as claimed in claim 8, wherein the ID marks are made of metal.

10. The substrate panel as claimed in claim 1, wherein the substrate panel is a printed circuit board.

11. The substrate panel as claimed in claim 1, wherein the ID marks are chosen from numbers, letters, text, special symbols, graphs, or combination of all.

12. The substrate panel as claimed in claim 1, wherein the substrate panel has a plurality of first scribe lines around the peripheries of the substrate strips, and each substrate strip has a plurality of second scribe lines around the peripheries of the substrate units and enclosed by the first scribe lines.
